(19) United States
(12) Patent Application Publication
(10) Pub. No.: US 2011/0291873 A1
(43) Pub. Date: Dec. 1, 2011

(54) DIFFERENTIAL AMPLIFIER AND PIPELINE A/D CONVERTER USING THE SAME

(75) Inventors: Toshiaki OZEKI, Osaka (JP); Takashi Morie, Osaka (JP)

(73) Assignee: PANASONIC CORPORATION, Osaka (JP)

(21) Appl. No.: 13/205,399

(22) Filed: Aug. 8, 2011

Related U.S. Application Data
(63) Continuation of application No. PCT/JP2009/004654, filed on Sep. 16, 2009.

(30) Foreign Application Priority Data
Mar. 9, 2009 (JP) 2009-055175

(51) Int. Cl. H03M 1/34; H03F 3/45

(52) U.S. Cl. 341/158; 330/253

(57) ABSTRACT

In a differential amplifier, input terminals to which a differential input is given are connected to gates of input transistors, respectively. One ends of capacitive devices are connected to sources of the input transistors, respectively. A switching section switches connection between the other ends of the capacitive devices and the input terminals according to a control clock at each phase.

### CROSS-REFERENCE TO RELATED APPLICATION

This is a continuation of PCT International Application PCT/JP2009/004654 filed on Sep. 16, 2009, which claims priority to Japanese Patent Application No. 2009-055175 filed on Mar. 9, 2009. The disclosures of these applications including the specifications, the drawings, and the claims are hereby incorporated by reference in their entirety.

### BACKGROUND

The present disclosure relates to a differential amplifier used in a pipeline A/D converter, etc.

FIG. 8 is a block diagram of a pipeline A/D converter. As shown in FIG. 8, a typical pipeline A/D converter 10 includes a plurality of cascade-connected gain stages 11 (stages 1-n) and an encoder 14. The gain stages 11 respectively output digital signals D1-Dn obtained by digital conversion of a received analog signal. And the gain stages 11 each adds or subtracts an analog quantity corresponding to an associated one of the digital signals D1-Dn to or from the received analog signal, and outputs an analog signal obtained, for example, by doubling the obtained value, to a subsequent one of the gain stages 11. The encoder 14 adds the digital signals D1-Dn output from the gain stages 11 with 1 bit shift per stage to generate a digital output of the pipeline A/D converter 10.

The lower part of FIG. 8 shows an example circuit configuration for each of the gain stages 11. FIG. 8 shows the circuit configuration of a stage 1 as a representative example, and the other ones of the gain stages 11 have the same configuration as that of the stage 1. The gain stages 11 each have a sub-A/D converter 12, a sub-D/A converter 13, and a switched capacitor circuit including a switch group, sampling capacitances Cs and Cf, and an amplifier 100A. In the gain stage 11 (the stage 1), a received analog input Vin is converted from analog to digital by the sub-A/D converter 12, and a digital value D1 is output. Also, the digital value D1 is converted to an analog value by the sub-D/A converter 13. An amplifier section realized by the switched capacitor circuit subtracts the analog value output from the sub-D/A converter 13 from the analog input Vin, and multiplies the obtained value by a gain (ideally, a gain of 2 in a 1.5 bit stage).

In the amplifier section of the gain stage 11, each switch is turned on at the phases φ1 or φ2 shown in a timing chart of FIG. 8. The following Equation 1 is obtained by controlling the switches using clocks of the different phases φ1 and φ2.

$$Vout = \frac{Cs + Cf}{Cf + \frac{Cs + Cf + Cp}{A}} \cdot Vin \pm \frac{Cs}{Cf + \frac{Cs + Cf + Cp}{A}} \cdot Vref \qquad [ Equation u 1 ]$$

In Equation 1, A is a DC gain of the amplifier 100A, and Vref is a reference voltage. In the 1.5 bit stage scheme, capacitance values of the sampling capacitances Cs and Cf are set so that the relationship Cs=Cf is satisfied, thereby achieving a gain of about 2. In Equation 1, Cp is a parasitic capacitance added to an input terminal of the amplifier 100A. Although not shown in FIG. 8, at the phase φ1, the amplifier 100A is in an active state, and in general, a differential input terminal is short-circuited to be reset so that an operation result for the previous phase does not remain as charge in a capacitance of a differential input. An output terminal can be also reset at the same time as resetting the differential input terminal.

To reduce the power consumption and area of pipeline A/D converters, U.S. Pat. No. 6,166,675 describes a double sampling technique in which in a pipeline A/D converter configured so that two-channel gain stages are controlled at each phase to process signals in parallel, thereby realizing high speed operation, a differential amplifier is shared by two channels to reduce the number of differential amplifiers and thus realize reduction in power consumption.

It is also described in “A 250-mW, 8-b, 52-MSamples/s Parallel-Pipelined A/D converter with Reduced Number of Amplifiers”, IEEE JOURNAL OF SOLID-STATE CIRCUITS, VOL. 32, NO. 3, MARCH 1997, an amplifier sharing technique in which, using a characteristic of a differential amplifier that the differential amplifier performs an active operation alternately in adjacent gain stages at opposite phases, the differential amplifier is shared by the adjacent gain stages in a time sharing manner.

As in a configuration in which a differential amplifier is shared in a time sharing manner such as the double sampling technique and the amplifier sharing technique, a problem arises in which charge at a previous phase is held as a history at an input capacitance or parasitic capacitance of the differential amplifier, and a charge operation result in a gain stage operation at a subsequent phase suffers interference. Based on a transfer function of Equation 1, as a result of storing an operation result for the previous phase in an input parasitic capacitance Cp of the differential amplifier, Equation 2 is obtained.

$$Vout = \frac{Cs + Cf}{Cf + \frac{Cs + Cf + Cp}{A}} \cdot Vin \pm \frac{Cs}{Cf + \frac{Cs + Cf + Cp}{A}} \cdot Vref - \frac{Cp}{Cs + ( 1 + A ) \cdot Cf + Cp} {Vout}_{- 1} \qquad [ Equation 2 ]$$

In Equation 2, Vout₁ is an output analog voltage Vout at the previous phase, and the last term in Equation 2 is a history term, expressing interference depending on the input signal at the previous phase.

Such interference with a signal by the history of charge causes degradation of integral non-linearity (INL), differential non-linearity (DNL), and total harmonic distortion (THD) of the pipeline A/D converter.

To avoid this problem, for example, there is a method in which a reset period is provided between an end of a phase and a start of a subsequent phase to reset the input terminal of the differential amplifier. However, this method causes increase in complexity of the control circuit, and the operation speed is reduced. Therefore, it is not preferable to use this method, in particular, in a technique for increasing the speed such as double sampling.

U.S. Pat. No. 7,304,598 describes a method in which using two differential amplifiers and switches respectively connected to positive and negative input terminals of the differential amplifiers, charge held in input capacitances and parasitic capacitances of the differential amplifiers are cancelled by connecting, at a first phase, the positive input terminals of the two differential amplifies together and the negative input terminals of the two differential amplifiers together and switching, at a second phase, the connection of the input terminals so that the positive and negative input terminals of one of the two amplifiers are connected to the negative and positive input terminals of the other one of the two differential amplifiers, respectively.

### SUMMARY

However, in the method of U.S. Pat. No. 7,304,598, in addition to the conventional gain stage configuration, the switches are added to a feedback loop from the output terminal to the input terminal in each differential amplifier, thus resulting in degradation of an operation settling characteristic.

Therefore, it is an object of the present disclosure to reduce, in a differential amplifier, the memory effect due to charge which remains in input terminals when the differential amplifier is shared in a time sharing manner, without causing degradation of the operation setting characteristic.

According to one embodiment, a differential amplifier includes: first and second input terminals to which a differential input is given; first and second input transistors whose gates are connected to the first and second input terminals, respectively; first and second capacitive devices whose one ends are connected to sources of the first and second input transistors, respectively; and a switching section configured to switch connection between the other ends of the first and second capacitive devices and the first and second input terminals according to a control clock at each phase.

Thus, according to the above-described embodiment, the capacitive devices connected to the first and second input terminals are switched around by the switching section at each phase. Accordingly, charge stored in the input capacitances of the input transistors and interconnect parasitic capacitances at a previous phase can be canceled by charge stored in the capacitive devices. Therefore, the memory effect due to the charge remaining in the input terminals when, for example, the differential amplifier is shared in a time sharing manner can be reduced. Moreover, since it is not necessary to add switches to a feedback loop from the output terminal to the input terminal in the differential amplifier, the operation settling characteristic is not degraded.

According to another embodiment, a differential amplifier includes: first and second input terminals to which a differential input is given; first and second input transistors whose gates are connected to the first and second input terminals, respectively; first and second capacitive devices; a first switching section configured to switch connection between one ends of the first and second capacitive devices and drains of the first and second input transistors according to a control clock at each phase; and a second switching section configured to switch connection between the other ends of the first and second capacitive devices and the first and second input terminals according to a control clock at each phase.

Thus, according to this embodiment, the capacitive devices connected to the first and second input terminals are switched around by the first and second switching sections at each phase. Accordingly, charge stored in the input capacitances of the input transistors and interconnect parasitic capacitances at a previous phase can be canceled by charge stored in the capacitive devices. Therefore, the memory effect due to the charge remaining in the input terminals when, for example, the differential amplifier is shared in a time sharing manner can be reduced. Moreover, since it is not necessary to add switches to a feedback loop from the output terminal to the input terminal in the differential amplifier, the operation settling characteristic is not degraded.

In a differential amplifier according to the present disclosure, capacitive devices connected to two input terminals are switched around by switching control at each phase, so that the memory effect due to charge stored in input terminals can be reduced.

### BRIEF DESCRIPTION OF THE DRAWINGS

FIG. 1 is a diagram illustrating a configuration of a differential amplifier according to a first embodiment.

FIG. 2 is a diagram illustrating a configuration of a differential amplifier according to a second embodiment.

FIG. 3 is a diagram illustrating a configuration of a differential amplifier according to a third embodiment.

FIG. 4 is a diagram illustrating a configuration of a differential amplifier according to a fourth embodiment.

FIG. 5 is a diagram illustrating a configuration of a differential amplifier according to a fifth embodiment.

FIG. 6 is a diagram illustrating a configuration of switches and a differential amplifier in a gain stage according to a sixth embodiment.

FIG. 7 is a timing chart showing switching control according to the sixth embodiment.

FIG. 8 is a diagram schematically illustrating a typical configuration of a pipeline A/D converter.

FIG. 9 is a circuit diagram of a gain stage to which a double sampling technique in which a differential amplifier is shared is applied.

### DETAILED DESCRIPTION

Embodiments of the present disclosure will be described in detail with reference to the accompanying drawings.

### First Embodiment

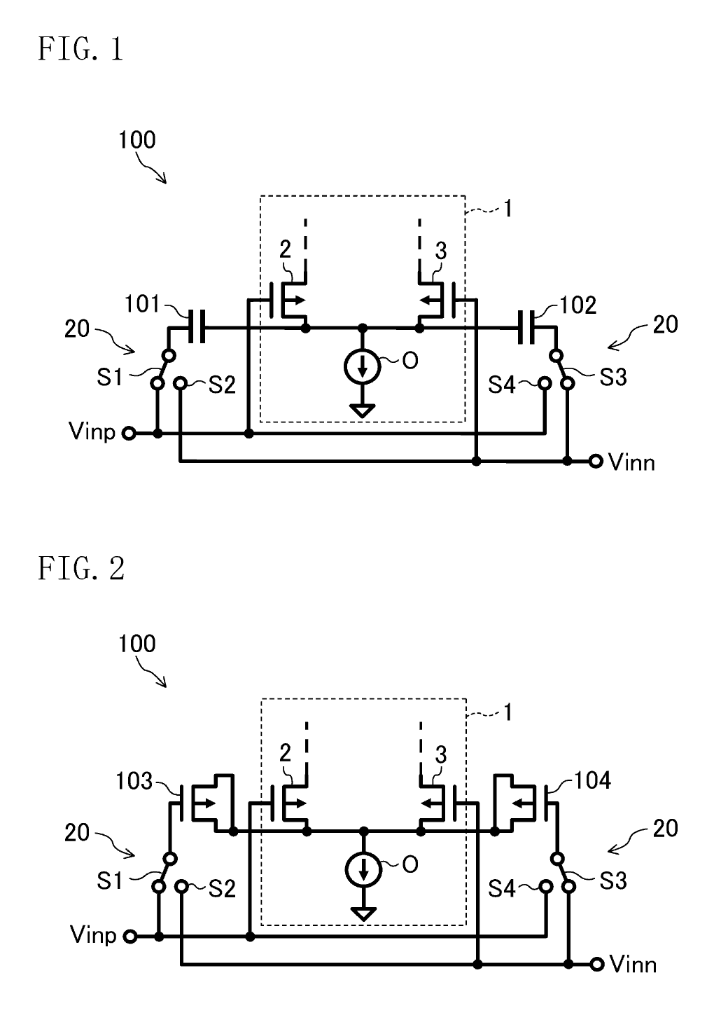

FIG. 1 is a diagram illustrating a configuration of a differential amplifier according to a first embodiment. The differential amplifier 100 of FIG. 1 includes a positive input terminal Vinp and a negative input terminal Vinn as first and second input terminals to which a differential input is given, a differential input section 1 including n-channel transistors 2 and 3 as first and second input transistors and a current source 0, first and second capacitive devices 101 and 102 whose one ends are respectively connected to sources of the transistors 2 and 3 (which are commonly connected to the current source 0), and a switching section 20 configured to switch connection between the other ends of the first and second capacitive devices 101 and 102 and the positive input terminal Vinp and the negative input terminal Vinn at each phase. Note that as the differential input section 1, a configuration having an n-channel transistor is shown for the sake of convenience, but the transistor type and circuit configuration of the differential input section 1 are not limited to those illustrated in FIG. 1. The same applies to other embodiments in this respect. Also, the capacitive devices 101 and 102 can be realized, for example, by metal-insulator-metal (MIM) capacitances and metal-oxide-metal (MOM) capacitances. However, as will be described later, the capacitive devices 101 and 102 can be also realized by p-channel and n-channel transistors.

The switching section 20 includes switches S1, S2, S3, and S4 as first through fourth switches. The switches S1 and S2 are provided respectively between the other end of the first capacitive device 101 and the positive input terminal Vinp and between the other end of the first capacitive device 101 and the negative input terminal Vinn. The switches S3 and S4 are provided respectively between the other end of the second capacitive device 102 and the negative input terminal Vinn and between the other end of the second capacitive device 102 and the positive input terminal Vinp. The switches S1 and S3 are turned on at the same phase φ1, and the switches S2 and S4 are turned on at the opposite phase φ2.

Note that in the configuration of FIG. 1, the one ends of the first and second capacitive devices 101 and 102 are directly connected to the sources of the transistors 2 and 3, but a switch may be provided therebetween.

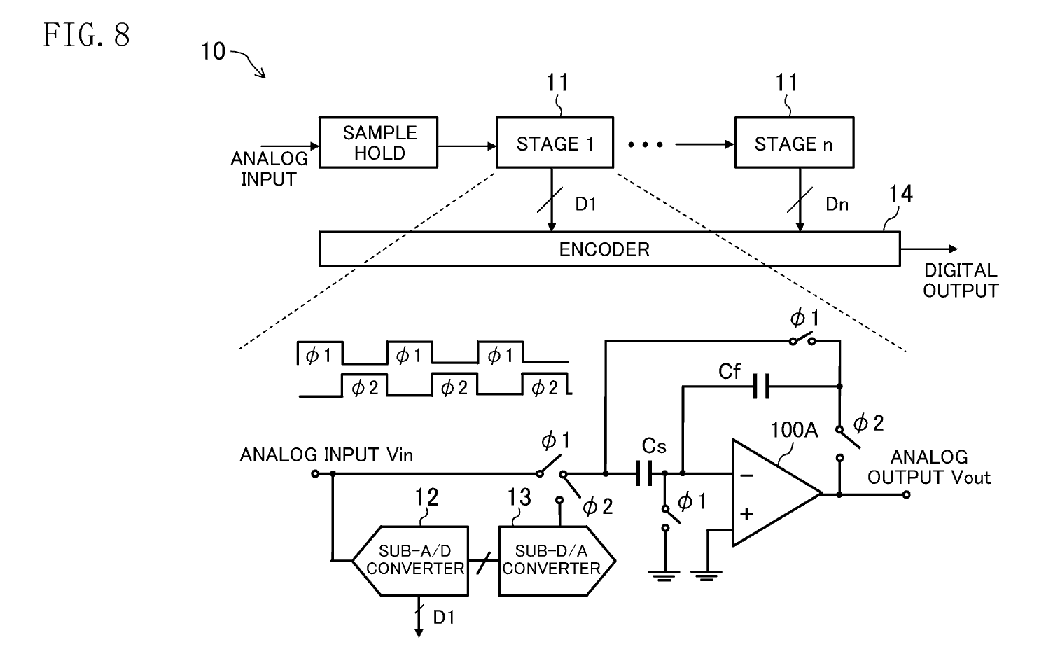

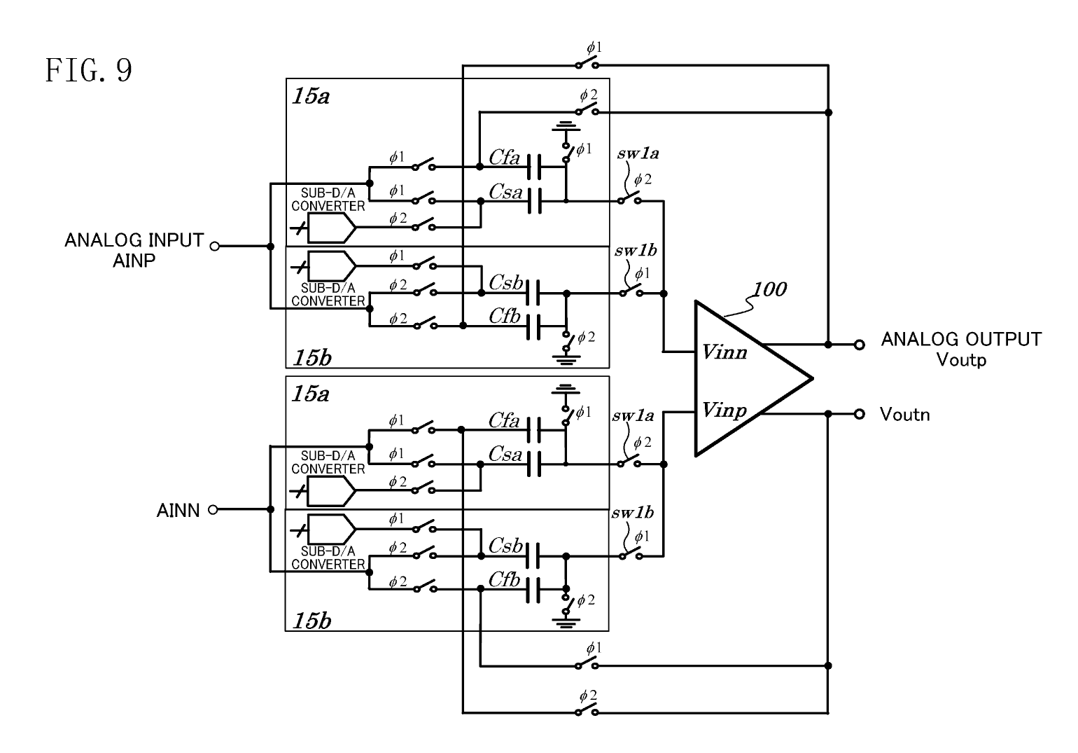

The differential amplifier 100 of FIG. 1 can be used in a configuration employing double sampling or amplifier sharing in which a differential amplifier is shared in a time sharing manner. FIG. 9 illustrates a configuration in which the differential amplifier 100 of FIG. 1 is employed in a gain stage to which the double sampling technique is applied. In the configuration of FIG. 9, two groups of switches and sampling capacitances as shown in FIG. 8 arranged in parallel to serve as channels 15a and 15b are provided for each of the positive input terminal Vinp and negative input terminal Vinn of the differential amplifier 100. Each of the input terminals Vinp and Vinn of the differential amplifier 100 is alternately connected to the two channels 15a and 15b by the switches sw1a and sw1b at each phase, and the differential amplifier 100 is shared in a time sharing manner. Thus, the operation speed can be substantially doubled without increasing the power consumption. Clocks to control the phases φ1 and φ2 are the same as those shown in the timing chart of FIG. 8.

The operation of the differential amplifier 100 of FIG. 1 when the differential amplifier 100 is used in double sampling will be described hereafter with reference to FIG. 9. Note that switching control of the differential amplifier 100 can be realized by the same clocks used in the gain stages of FIG. 9. The operation of the differential amplifier 100 at each phase will be described in detail below.

[Operation of Differential Amplifier at φ1]

At the phase φ1, in the gain stage of FIG. 9, the switching groups in the channels 15a are at a sampling phase, analog inputs AINP and AINN are each connected to the capacitive devices Csa and Cfa, the switches sw1a provided between the capacitive devices Csa and Cfa and the input terminals Vinn and Vinp of the differential amplifier 100 are off. At this time, the switching groups in the channels 15b are at a hold phase, and the capacitive devices Csb and Cfb and the input terminals Vinn and Vinp of the differential amplifier 100 are connected by the switches sw1b. In the configuration of FIG. 1, the switches S1 and S3 are turned on, the switches S2 and S4 are turned off, the positive input terminal Vinp and the capacitive device 101 are connected together, and the negative input terminal Vinn and the capacitive device 102 are connected together (a connected state shown in FIG. 1).

As a result of convergence of an operation for φ1, a potential difference between the input terminals of the differential amplifier 100 is expressed by

Vinp−Vinn=(Voutp−Voutn)/A,

where A is a DC gain of the differential amplifier 100. At the end of φ1, charge Qin2 obtained from Equation 3 below is stored in the positive input terminal Vinp.

Qin2=Vinp×(Cin+Cp)+Vinp×(C101+C101p), [Equation 3]

where Cin is an input capacitance (including a gate-drain input capacitance, a gate-source input capacitance, and a gate-body input capacitance) of the transistor, and Cp is an interconnect parasitic capacitance of a gate of the input transistor, C101 is a capacitance value of the capacitive device 101, and C101p is an interconnect parasitic capacitance of the capacitive device 101. Similarly, charge expressed by the following equation is stored in the negative input terminal Vinn.

Qin3=Vinn×(Cin+Cp)+Vinn×(C102+C102p),

where C102 is a capacitance value of the capacitive device 102, and C102p is an interconnect parasitic capacitance of the capacitive device 102.

[Operation of Differential Amplifier at φ2]

At the phase φ2, in contrast to the operation at the phase φ1, the switches sw1a are turned on, the switch groups in the channels 15a are at a hold phase, and the switch groups in the channels 15b are at a sampling phase. In the differential amplifier 100, the switches 51 and S3 are turned off, and the switches S2 and S4 are turned on. Thus, in contrast to the operation at the phase φ1, the capacitive device 102 is connected to the positive input terminal Vinp, and the capacitive device 101 is connected to the negative input terminal Vinn.

The amount of the charge stored in the input transistors 2 and 3 and the capacitive devices 101 and 102 is held at the end of the phase φ1. Therefore, only the term for the charge stored in the capacitive devices is replaced, and the charge Qin2′ of the positive input terminal Vinp at the shift to the phase φ2 is expressed by

Qin2′=Vinp×(Cin+Cp)+Vinn×(C102+C102p).

In this case,

Vinn=−Vinp

holds. Therefore,

Qun2′=Vinp×(Cin−C102+Cp−C102p)

is given.

When the capacitive devices and the interconnect parasitic capacitances are set so that

Cin=C102=C101, and Cp=C102p=C101p

is satisfied, the charge stored at the phase φ1 can be canceled.

Similarly, for the negative input terminal Vinn, the charge Qin3′ at the shift to the phase φ2 is expressed by

Qin3′=Vinn×(Cin−C101+Cp−C101p),

and the charge can be canceled. Thus, the charge stored in the positive and negative input terminals at the end of the phase φ1 can be canceled, and therefore, even at the shift to the phase φ2, the operation results in the channels 15b suffer no interference by the memory effect.

Based on the foregoing, by reducing the history term in Equation 2, even when the differential amplifier 100 is shared in a time sharing manner, an operation can be performed in a gain stage without causing reduction of accuracy. In this embodiment, as opposed to U.S. Pat. No. 7,304,598, the memory effect of the residual charge can be reduced without causing degradation of the operation settling characteristic.

As described above, according to this embodiment, the capacitive devices are connected to the input terminals of the differential amplifier, and connection between the capacitive devices and the positive and negative terminals is switched at each phase. Thus, the charge stored in the capacitances in the input terminals at the previous phase can be reduced, and the memory effect due to the charge remaining in the input terminals when the differential amplifier is shared in a time sharing manner can be reduced.

### Second Embodiment

FIG. 2 is a diagram illustrating a configuration of a differential amplifier according to a second embodiment. The differential amplifier 100 of FIG. 2 has a configuration in which the capacitive devices in the configuration of FIG. 1 are composed of dummy transistors. Specifically, the differential amplifier 100 of FIG. 2 includes a positive input terminals Vinp and a negative input terminal Vinn as first and second input terminals to which a differential input is given, a differential input section 1 including n-channel transistors 2 and 3 as first and second input transistors and a current source 0, first and second dummy transistors 103 and 104 whose sources are respectively connected to sources of the transistors 2 and 3 (which are commonly connected to the current source 0), and a switching section 20 configured to switch connection between gates of the first and second dummy transistors 103 and 104 and the positive input terminal Vinp and the negative input terminal Vinn at each phase. Note that the type of the dummy transistors 103 and 104 is not limited to the same as the input transistors 2 and 3, but in this embodiment, n-channel transistors of the same type are used as the dummy transistors 103 and 104.

The switching section 20 includes switches 51, S2, S3, and S4 as first through fourth switches. The switches 51 and S2 are provided respectively between the gate of the first dummy transistor 103 and the positive input terminal Vinp and between the gate of the first dummy transistor 103 and the negative input terminal Vinn. The switches S3 and S4 are provided respectively between the gate of the second dummy transistor 104 and the negative input terminal Vinn and between the gate of the second dummy transistor 104 and the positive input terminal Vinp. Similar to the first embodiment, the switches 51 and S3 are turned on at the same phase φ1, and the switches S2 and S4 are turned on at the opposite phase φ2.

In the configuration of FIG. 2, drains of the first and second dummy transistors 103 and 104 are respectively short-circuited to sources thereof. However, the drains may be in a not-connected state.

Similar to Equation 3 shown in the first embodiment, charge stored in the positive input terminal Vinp at the end of the phase φ1 is expressed by Equation 4 below.

Qin2=Vinp×(Cin+Cp)+Vinp×(Cdumin+Cdump), [Equation 4]

where Cdumin is an input capacitance of the dummy transistor and Cdump is an interconnect parasitic capacitance of the gate of the dummy transistor. An input capacitance Cin of the input transistor includes a gate-source capacitance Cgs, a gate-drain capacitance Cgd, and a gate-body capacitance Cgb, and the input capacitances of the transistor having the same size as that of the input transistor are respectively indicated by Cgs, Cgd, and Cgb. Similarly, the input capacitance Cdumin can be also divided in the above-described manner, and, when drain and source terminals are short-circuited to each other, Cgd=Cgs holds.

At the shift to the phase φ2, the term of the charge of the dummy transistor is replaced, and charge Qin2′ stored in the positive input terminal Vinp is expressed by

Qin2′=Vinp×(Cin−Cdumin+Cp−Cdump).

For example, when the size W of the dummy transistor is set to be equal to the size W of the input transistor 2, in contrast to the input capacitance of the input transistor expressed by

Cin=Cgs+Cgd+Cgb,

the input capacitance of the dummy transistor is

Cdumin=2×Cgs+Cgb.

### Thus,

Cin−Cdumin=Cgd−Cgs

holds, and the charge can be greatly reduced. Qin2′ can be further reduced by setting the interconnect parasitic capacitance of the input transistor and the dummy transistor to be equal to each other.

As described above, according to this embodiment, the dummy transistors are connected to the positive and negative input terminals of the differential amplifier, and connection between the dummy transistors and the positive and negative terminals is switched at each phase. Thus, the charge stored in the capacitance of the input terminal at the previous phase can be reduced, and the memory effect due to charge remaining in the input terminals when the differential amplifier is shared in a time sharing manner can be reduced.

### Third Embodiment

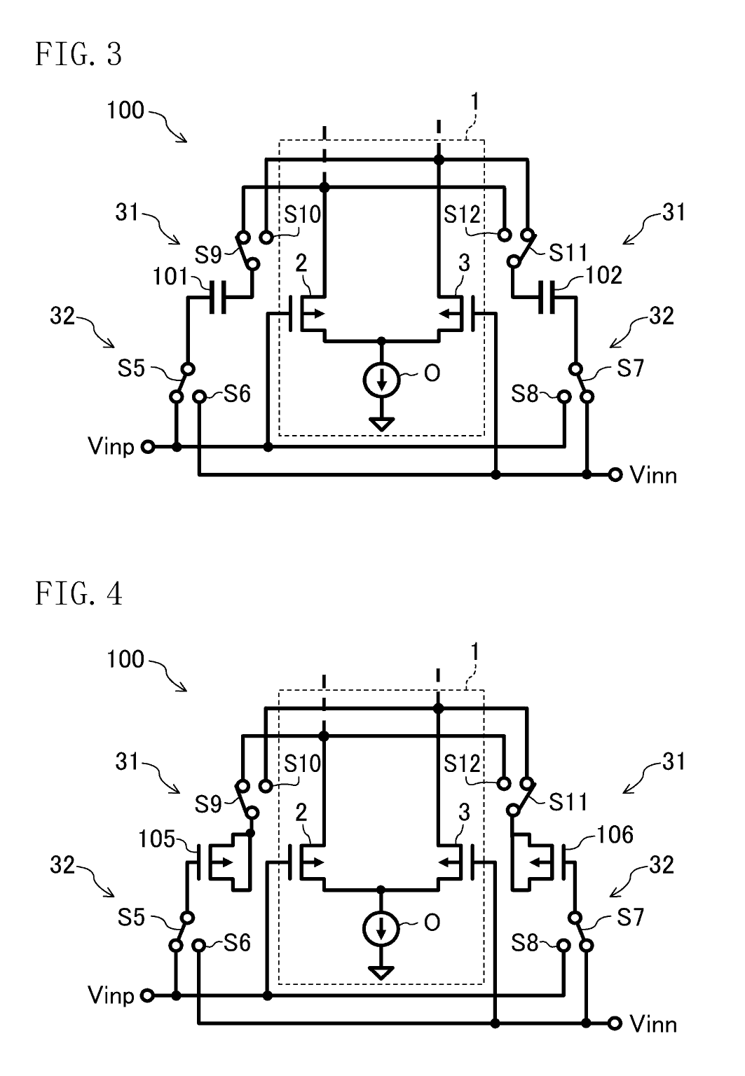

FIG. 3 is a diagram illustrating a configuration of a differential amplifier according to a third embodiment. The differential amplifier 100 of FIG. 3 includes a positive input terminal Vinp and a negative input terminal Vinn as first and second input terminals to which a differential input is given, a differential input section 1 including n-channel transistors 2 and 3 as first and second input transistors and a current source 0, first and second capacitive devices 101 and 102, a first switching section 31 configured to switch connection between one ends of the first and second capacitive devices 101 and 102 and drains of the input transistors 2 and 3 at each phase, and a second switching section 32 configured to switch connection between the other ends of the first and second capacitive devices 101 and 102 and the positive input terminal Vinp and the negative input terminal Vinn at each phase.

The first switching section 31 includes switches S9, S10, S11, and S12 as first through fourth switches. The switches S9 and S10 are provided respectively between the one end of the first capacitive device 101 and the drain of the input transistor 2 and between the one end of the first capacitive device 101 and the drain of the input transistor 3. The switches S11 and S12 are provided respectively between the one end of the second capacitive device 102 and the drain of the input transistor 3 and between the one end of the second capacitive device 102 and the drain of the input transistor 2.

The second switching section 32 includes switches S5, S6, S7, and S8 as fifth through eighth switches. The switches S5 and S6 are provided respectively between the other end of the first capacitive device 101 and the positive input terminal Vinp and between the other end of the first capacitive device 101 and the negative input terminal Vinn. The switches S7 and S8 are provided respectively between the other end of the second capacitive device 102 and the negative input terminal Vinn and between the other end of the second capacitive device 102 and the positive input terminal Vinp.

The switches S5, S7, S9, and S11 are turned on at the same phase φ1, and the switches S6, S8, S10, and S12 are turned on at the opposite phase φ2.

The operation of the differential amplifier 100 at each of the phases φ1 and φ2 will be described.

[Operation of Differential Amplifier at φ1]

At the phase φ1, the switches S5, S7, S9, and S11 are turned on, and the switches S6, S8, S10, and S12 are turned off. As a result, the first capacitive device 101 is connected to the positive input terminal Vinp and the drain of the input transistor 2 via the switches S5 and S9, and the second capacitive device 102 is connected to the negative input terminal Vinn and the drain of the input transistor 3 via the switches S7 and S11 (a connected state shown in FIG. 3).

As a result of convergence of an operation for φ1, a potential difference between the input terminals of the differential amplifier 100 is expressed by

Vinp−Vinn=(Voutp−Voutn)/A.

At the end of φ1, charge Qin2 obtained from the following Equation 3 which is shown in the first embodiment is stored in the positive input terminal Vinp.

Qin2=Vinp×(Cin+Cp)+Vinp×(C101+C101p)

Similarly, in the negative input terminal Vinn, charge expressed by

Qin3=Vinn×(Cin+Cp)+Vinn×(C102+C102p)

is stored.

[Operation of Differential Amplifier at φ2]

At the phase φ2, the switches S5, S7, S9, and S11 are turned off, and the switches S6, S8, S10, and S12 are turned on. Thus, in contrast to the operation at the phase φ1, the first capacitive device 101 is connected to the negative input terminal Vinn and the drain of the input transistor 3 via the switches S6 and S10, and the second capacitive device 102 is connected to the positive input terminal Vinp and the drain of the input transistor 2 via the switches S8 and S12.

The amount of the charge stored in the input transistors 2 and 3 and the capacitive devices 101 and 102 is held at the end of the phase φ1. Therefore, the amount of the charge Qin2′ of the positive input terminal Vinp at the shift to the phase φ2 is expressed by

Qin2′=Vinp×(Cin−C102+Cp−C102p),

and when the capacitive devices and the interconnect parasitic capacitances are set so that Cin

=C102=C101 and Cp=C102p=C101p are satisfied, the charge stored at the phase φ1 can be canceled.

Similarly, for the negative input terminal Vinn,

Q3′=Vinn×(Cin−C101+Cp−C101p)

holds, and the charge can be canceled. Thus, in this embodiment, the memory effect due to interference by the charge remaining in the input terminal can be reduced.

As described above, according to this embodiment, the capacitive devices are connected to the input terminals of the differential amplifier, and connection between the capacitive devices and the positive and negative terminals is switched at each phase. Thus, the charge stored in the capacitances in the input terminals at the previous phase can be reduced, and the memory effect due to the charge remaining in the input terminals when the differential amplifier is shared in a time sharing manner can be reduced.

### Fourth Embodiment

FIG. 4 is a diagram illustrating a configuration of a differential amplifier according to a fourth embodiment. The differential amplifier 100 of FIG. 4 has a configuration in which the capacitive devices in the configuration of FIG. 3 are composed of dummy transistors. Specifically, the differential amplifier 100 of FIG. 4 includes a positive input terminal Vinp and a negative input terminal Vinn as first and second input terminals to which a differential input is given, a differential input section 1 including n-channel transistors 2 and 3 as first and second input transistors and a current source 0, first and second dummy transistors 105 and 106, a first switching section 31 configured to switch connection between drains of the first and second dummy transistors 105 and 106 and drains of the input transistors 2 and 3 at each phase, and a second switching section 32 configured to switch connection between gates of the first and second dummy transistors 105 and 106 and the positive input terminal Vinp and the negative input terminal Vinn at each phase. Note that similar to the second embodiment, the type of the dummy transistors 105 and 106 is not limited to the same as the input transistors 2 and 3, but in this embodiment, n-channel transistors of the same type are used as the dummy transistors 105 and 106.

The first switching section 31 includes switches S9, S10, S11, and S12 as first through fourth switches. The switches S9 and S10 are provided respectively between the drain of the first dummy transistor 105 and the drain of the input transistor 2 and between the drain of the first dummy transistor 105 and the drain of the input transistor 3. The switches S11 and S12 are provided respectively between the drain of the second dummy transistor 106 and the drain of the input transistor 3 and between the drain of the second dummy transistor 106 and the drain of the input transistor 2.

The second switching section 32 includes switches S5, S6, S7, and S8 as fifth through eighth switches. The switches S5 and S6 are provided respectively between the gate of the first dummy transistor 105 and the positive input terminal Vinp and between the gate of the first dummy transistor 105 and the negative input terminal Vinn. The switches S7 and S8 are provided respectively between the gate of the second dummy transistor 106 and the negative input terminal Vinn and between the gate of the second dummy transistor 106 and the positive input terminal Vinp.

The switches S5, S7, S9, and S11 are turned on at the same phase φ1 (a connected state shown in FIG. 4), and the switches S6, S8, S10, and S12 are turned on at the opposite phase φ2.

Note that in the configuration of FIG. 4, sources of the first and second dummy transistors 105 and 106 are respectively short-circuited to the drains thereof. However, the sources may be in a not-connected state.

Charge Qin2 stored in the positive input terminal Vinp at the end of the phase φ1 is expressed by

Qin2=Vinp×(Cin+Cp)+Vinp×(Cdumin+Cdump),

which is the same as Equation 4 shown in the second embodiment.

At the shift to the phase φ2, charge Qin2′ stored in the positive input terminal Vinp is expressed by

Qin2′=Vinp×(Cin−Cdumin+Cp−Cdump).

Therefore, similar to the second embodiment, for example, when the size W of the dummy transistor is set to be equal to the size W of the input transistor 2, in contrast to the input capacitance of the input transistor expressed by

Cin=Cgs+Cgd+Cgb,

the input capacitance of the dummy transistor is

Cdumin=2×Cgd+Cgb.

### Thus,

Cin−Cdumin=Cgs−Cgd

holds, and the amount of charge can be greatly reduced. Similar to the second embodiment, when Cgd and Cgs are compared to each other, the effect of components of Cgd is large because of the mirror effect due to a transconductance gm of the input transistor and a drain side load resistance of the input transistor, and therefore, adjustment of the size of the dummy transistors is necessary according to such effects.

As described above, according to this embodiment, the dummy transistors are connected to the positive and negative input terminals of the differential amplifier, and connection between the dummy transistors and the positive and negative terminals is switched at each phase. Thus, the charge stored in the capacitances in the input terminals at the previous phase can be reduced, and the memory effect due to the charge remaining in the input terminals when the differential amplifier is shared in a time sharing manner can be reduced.

### Fifth Embodiment

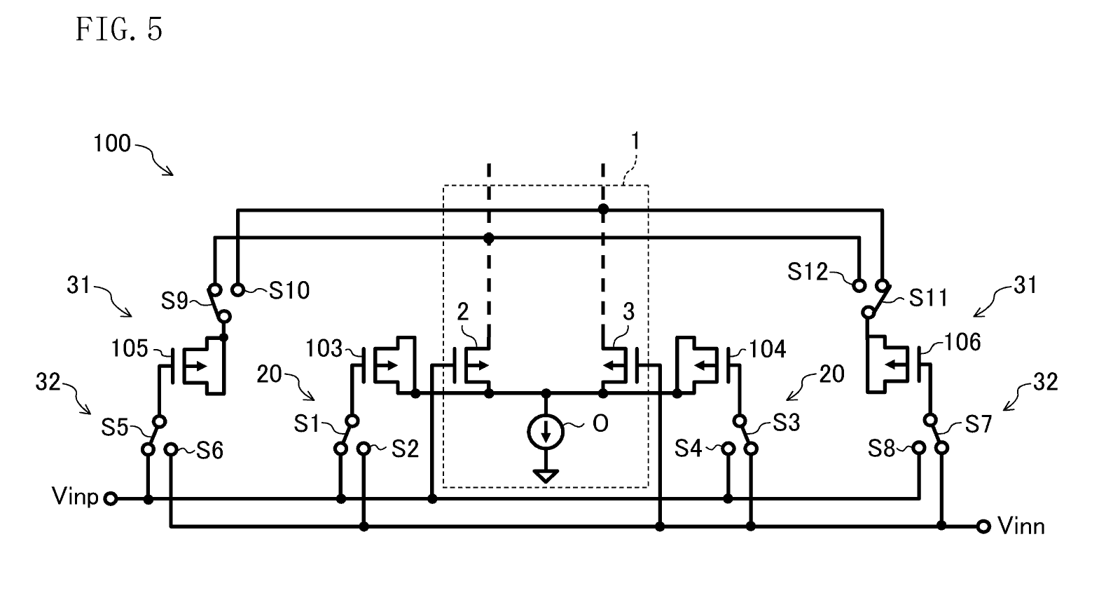

FIG. 5 is a diagram illustrating a configuration of a differential amplifier according to a fifth embodiment. The differential amplifier 100 of FIG. 5 includes a differential input section 1, the dummy transistors 103 and 104 and the switching section 20 of FIG. 2, and the dummy transistors 105 and 106 and the first and second switching sections 31 and 32 of FIG. 4. The operation of the differential amplifier 100 is similar to that described in the second and fourth embodiments, and switching control is performed at the phases φ1 and φ2 in the manner described in the second and fourth embodiments.

In the configuration of FIG. 5, a drain and a source are short-circuited in each of the dummy transistors 103, 104, 105, and 106. However, the dummy transistors 103, 104, 105, and 106 only need to be configured so that at least a source is in a connected state in the dummy transistors 103 and 104 and at least a drain is in a connected state in the dummy transistors 105 and 106.

It is assumed that the size W of the dummy transistors 103, 104, 105, and 106 is set to be half the size of the input transistors 2 and 3. In this case, since a gate-drain capacitance of the dummy transistor 103 is equal to a gate-source capacitance thereof and the size of the dummy transistor 103 is half the size of the input transistor, the input capacitance is

2×(½)×Cgs.

Also, since a gate-source capacitance of the dummy transistor 105 is equal to a gate-drain capacitance thereof and the size of the dummy transistor 105 is half the size of the input transistor, the input capacitance is

2×(½)×Cgd.

The gate-drain capacitance, the gate-source capacitance, and the gate-body capacitance of the input transistor are respectively equal to the sum of the gate-drain capacitances, the sum of the gate-source capacitances, and the sum of the gate-body capacitances of the two dummy transistors. Therefore, the charge Qin2′ of the positive input terminal Vinp at the time when the phase φ1 is ended and the phase φ2 is started is expressed by

$$\begin{matrix}{Qin}^{2 ′} = Vinp \times ( Cgs + Cgd + Cgb + Cp ) - \\ Vinp \times \{ Cgs + Cgd + 2 \times ( 1 / 2 ) \times Cgb + 2 \times Cdump \} \\ = Vinp ( Cp - 2 \times Cdump )\end{matrix}$$

The charge can be completely canceled by adjusting the interconnect parasitic capacitance of the dummy transistors relative to the interconnect parasitic capacitance of the input transistor.

Here, a simulation was performed under the condition where the DC gain A of the differential amplifier was designed to be 40 dB, the reference voltage Vref was 0.5 V, and each of the sampling capacitances Cs and Cf was equal to the parasitic capacitance Cp (Cs=Cf=Cp). As a result of the simulation, in the conventional technique, an error of 5.1 mV occurred due to the memory effect. In contrast, by providing the dummy transistors as in this embodiment, an error due to the memory effect was advantageously reduced to 0.3 mV.

As described above, according to this embodiment, the dummy transistors are connected to the positive and negative input terminals of the differential amplifier, and connection between the dummy transistors and the positive and negative terminals is switched at each phase. Thus, the charge stored in the capacitance of the input terminal at the previous phase can be reduced, and the memory effect due to charge remaining in the input terminals when the differential amplifier is shared in a time sharing manner can be reduced.

### Sixth Embodiment

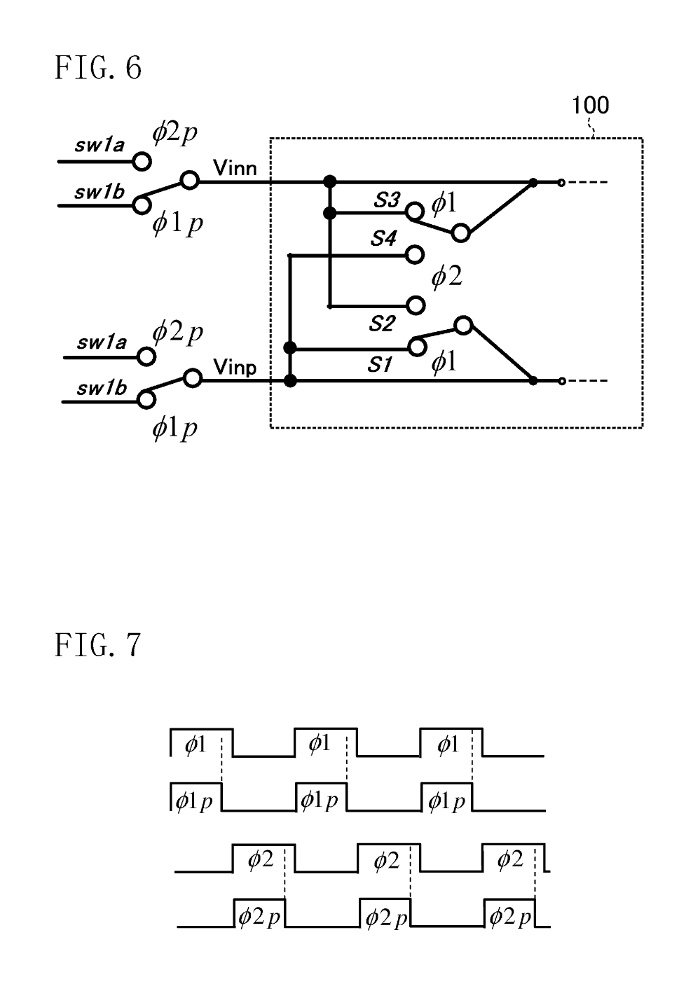

FIG. 6 is a diagram illustrating a peripheral circuit configuration of a differential amplifier according to a sixth embodiment. FIG. 7 is a timing chart showing switching control in FIG. 6.

Switches sw1a and sw1b shown in FIG. 6 correspond to the switches sw1a and sw1b of FIG. 9 for switching a differential input of the differential amplifier 100 between the channels 15a and 15b in the gain stage. Note that in this embodiment, the configuration including the switches 51, S2, S3, and S4 of the second embodiment is shown as the differential amplifier 100 (other components are not shown). However, the differential amplifier 100 of FIG. 6 is not limited to thereto, but may be realized using any one of the differential amplifiers of the first through fifth embodiments.

The timing chart of FIG. 7 corresponds to the switching operation in FIG. 6, yip is a clock which falls before φ1 falls, and, similarly, φ2p is a clock which falls before φ2 falls. The switch sw1b and the switches 51 and S3 are turned on at rising edges of the phases φ1 and φp, the switch sw1b is turned off at a falling edge of the phase φ1p, and the switches S1 and S3 are turned off at a falling edge of the phase φ1. Thus, charge such as charge injection flowing in from the switch sw1b when the switch sw1b is turned off is held as charge in the gate capacitances of the input transistor and the dummy transistor connected to the positive input terminal Vinp and the negative input terminal Vinn, since the switches S1 and S3 are on.

When the switch sw1b and the switches S1 and S3 are turned off at the same time, the amount of in-flow charge from the switch sw1b cannot be determined due to a small timing difference or a clock field through difference, and a difference between the charge stored in the dummy transistor and the charge store in the input transistor arises. However, as in this embodiment, by turning off the switch sw1b first, the amounts of charges stored in the dummy transistor and the input transistor can be caused to be constant. The same thing can be said about the switch sw1a and the switches S2 and S4 which are controlled by the phases φ2 and φ2p.

As described above, in this embodiment, a timing of turning off the switches for switching a differential input of the differential amplifier in the gain stage is set before the switching control in the differential amplifier. Thus, the charge stored in the capacitances in the input terminals at the previous phase can be reduced, and the memory effect due to the charge remaining in the input terminals when the differential amplifier is shared in a time sharing manner can be reduced.

In a differential amplifier according to the present disclosure, memory effect due to charge stored in differential input transistors can be reduced, and thus, the differential amplifier of the present disclosure is useful, for example, in reducing degradation of characteristics of a pipeline A/D converter capable of performing high speed operation.

What is claimed is:

1. A differential amplifier, comprising:
first and second input terminals to which a differential input is given;
first and second input transistors whose gates are connected to the first and second input terminals, respectively;
first and second capacitive devices whose one ends are connected to sources of the first and second input transistors, respectively; and
a switching section configured to switch connection between the other ends of the first and second capacitive devices and the first and second input terminals according to a control clock at each phase.

2. The differential amplifier of claim 1, wherein
the switching section includes
first and second switches provided respectively between the other end of the first capacitive device and the first input terminal and between the other end of the first capacitive device and the second input terminal, and
third and fourth switches provided respectively between the other end of the second capacitive device and the second input terminal and between the other end of the second capacitive device and the first input terminal.

3. The differential amplifier of claim 1, wherein
the switching section provides connection between the other end of the first capacitive device and the first input terminal and connection between the other end of the second capacitive device and the second input terminal at a first phase, and provides connection between the other end of the second capacitive device and the first input terminal and connection between the other end of the first capacitive device and the second input terminal at a second phase.

4. The differential amplifier of claim 1, wherein
the differential amplifier is shared between two gain stages in a pipeline A/D converter in a time sharing manner.

5. The differential amplifier of claim 1, wherein
the first and second capacitive devices are composed of first and second dummy transistors, respectively, and
the first and second dummy transistors whose sources are connected to the sources of the first and second input transistors, and gates are connected to the switching section.

6. The differential amplifier of claim 5, wherein
the switching section includes
first and second switches provided respectively between the gate of the first dummy transistor and the first input terminal and between the gate of the first dummy transistor and the second input terminal, and
third and fourth switches provided respectively between the gate of the second dummy transistor and the second input terminal and between the gate of the second dummy transistor and the first input terminal.

7. A differential amplifier, comprising:
first and second input terminals to which a differential input is given;
first and second input transistors whose gates are connected to the first and second input terminals, respectively;
first and second capacitive devices;
a first switching section configured to switch connection between one ends of the first and second capacitive devices and drains of the first and second input transistors according to a control clock at each phase; and
a second switching section configured to switch connection between the other ends of the first and second capacitive devices and the first and second input terminals according to a control clock at each phase.

8. The differential amplifier of claim 7, wherein
the first switching section includes
first and second switches provided respectively between one end of the first capacitive device and the drain of the first input transistor and between the one end of the first capacitive device and the drain of the second input transistor, and
third and fourth switches provided respectively between one end of the second capacitive device and the drain of the first input transistor and between the one end of the second capacitive device and the drain of the second input transistor, and
the second switching section includes
fifth and sixth switches provided respectively between the other end of the first capacitive device and the first input terminal and between the other end of the first capacitive device and the second input terminal, and
seventh and eighth switches provided respectively between the other end of the second capacitive device and the first input terminal and between the other end of the second capacitive device and the second input terminal.

9. The differential amplifier of claim 7, wherein
the first switching section provides connection between the one end of the first capacitive device and the drain of the first input transistor and connection between the one end of the second capacitive device and the drain of the second input transistor at a first phase, and provides connection between the one end of the second capacitive device and the drain of the first input transistor and connection between the one end of the first capacitive device and the drain of the second input transistor at a second phase, and
the second switching section provides connection between the other end of the first capacitive device and the first input terminal and connection between the other end of the second capacitive device and the second input terminal at the first phase, and provides connection between the other end of the second capacitive device and the first input terminal and connection between the other end of the first capacitive device and the second input terminal at the second phase.

10. The differential amplifier of claim 7, wherein
the differential amplifier is shared between two gain stages in a pipeline A/D converter in a time sharing manner.

11. The differential amplifier of claim 7, wherein
the first and second capacitive devices are composed of first and second dummy transistors, respectively, and
the first and second dummy transistors whose drains are connected to the first switching section, and gates are connected to the second switching section.

12. The differential amplifier of claim 11, wherein
the first switching section includes
first and second switches provided respectively between the drain of the first dummy transistor and the drain of the first input transistor and between the drain of the first dummy transistor and the drain of the second input transistor, and
third and fourth switches provided respectively between the drain of the second dummy transistor and the drain of the first input transistor and between the drain of the second dummy transistor and the drain of the second input transistor, and
the second switching section includes
fifth and sixth switches provided respectively between the gate of the first dummy transistor and the first input terminal and between the gate of the first dummy transistor and the second input terminal, and
seventh and eighth switches provided respectively between the gate of the second dummy transistor and the first input terminal and between the gate of the second dummy transistor and the second input terminal.

13. A pipeline A/D converter, comprising: a gain stage,
wherein
the gain stage includes
the differential amplifier of claim 1,
a sampling capacitive device, and
a switch provided between the first and second input terminals of the differential amplifier and the sampling capacitive device, and
a control timing of turning off the switch is set before a control timing of turning off the switching section of the differential amplifier.

14. A pipeline A/D converter, comprising: a gain stage
wherein
the gain stage includes
the differential amplifier of claim 7,
a sampling capacitive device,
a switch provided between the first and second input terminals of the differential amplifier and the sampling capacitive device, and
a control timing of turning off the switch is set before a control timing of turning off the first and second switching sections of the differential amplifier.
